(19) United States
(12) Patent Application Publication
(10) Pub. No.: US 2004/0058554 A1
(43) Pub. Date: Mar. 25, 2004

(54) Dry etching method

(76) Inventors: Masaru Izawa, Tokyo (JP); Shinichi Tachi, Sayama-shi (JP); Ken?apos;etsu Yokogawa, Tsurugashima-shi (JP); Nobuyuki Negishi, Kokubunji-shi (JP); Naoyuki Kofuji, Tokyo (JP); Naoshi Itabashi, Tokyo (JP); Seiji Yamamoto, Tokyo (JP); Kazue Takahashi, Kudamatsu-shi (JP)

Correspondence Address: MATTINGLY, STANGER & MALUR, Suite 370, 1800 Diagonal Rd., Alexandria, VA, 22314, US

(21) Appl. No.: 10/675,973

(22) Filed: Oct. 2, 2003

Related U.S. Application Data
(63) Continuation of application No. 09/373,723, filed on Aug. 13, 1999, now abandoned.

(30) Foreign Application Priority Data
Aug. 6, 1999 (JP) 11-224080

(51) Int. Cl. H01L 21/302; H01L 21/461

(52) U.S. Cl. 438/726; 438/728; 438/732

(57) ABSTRACT

In order to provide an etching method for silicone oxide film by fluorocarbon plasma in semiconductor production, which is superior in precise manufacturing and highly selective to resist and silicone nitride film, two kinds of electronic temperature regions are generated in plasma, and a generation ratio of CF₂/F is controlled independently from a generation amount of ions by making areas of these two electronic temperature regions variable with a magnetic field gradient and a distance between a wafer and a wafer facing plane.

### BACKGROUND OF THE INVENTION

The present invention relates to a dry etching method using for fine manufacturing of semiconductor devices, particularly, to a dry etching method for realizing high-precision dry etching manufacturing of silicone oxide film.

In order to connect electrically transistor structures formed on a wafer with metallic circuits to be connected, and to connect electrically the metallic circuits each other, contact holes are formed in an insulating film (it means a thin film containing SiO₂ as a main component, or a material having a low dielectric constant (Low-K film) such as an organic film, and it is called as an oxide film, hereinafter), and the contact holes are filled with an electric conductor. In accordance with the dry etching process, the contact holes are formed by the steps of introducing an etching gas into a vacuum chamber, generating a plasma by applying high frequency waves, or microwaves to the etching gas, and etching the oxide film selectively with active species and ions generated in the plasma. During the etching process, a resist thin film being reprinted with a hole pattern is formed on the oxide film. In accordance with the contact holes manufacturing, the oxide film must be etched selectively to the resist film, a circuit layer under the contact holes, and silicone forming the transistors. Moreover, in accordance with a dry etching method; wherein gate electrodes of field-effect transistor formed on a wafer are covered with a second insulating film made of a material different from the insulating film between the circuit layers, and a source region and a drain region are connected to the circuit layer; a selectivity of the second insulating film is required, because the second insulating film is appeared in the contact holes during the etching process. The contact manufacturing is called as a self-aligning contact (SAC), and a silicone nitride film is used as the second insulating film.

The contact holes manufacturing is performed by the steps of introducing fluorocarbon gases such as CF₄, CHF₃, C₄F₈, C₄F₆, C₅F₈, and Ar gas into an etching apparatus, and etching the wafer under a condition, wherein a bias voltage (Vpp voltage) of 1.5-2.0 kV is applied to the wafer, by high frequency plasma discharging in a gas pressure condition of 4 Pa-10 Pa. When the thickness of the oxide film between the circuit layers is thick, and an aspect ratio (a ratio of depth/diameter) of the contact hole is high, oxygen gas has been added in order to increase an aperture of the hole, and CO gas has been added in order to increase selectivity of the resist and the silicone nitride film.

In examples other than the oxide film etching, for example in manufacturing of the gate electrode, a mixed gas of chlorine gas, hydrogen bromide gas, and oxygen gas has been used. Anisotropic manufacturing has been controlled by adding oxygen. However, when polycrystalline Si of p-type and n-type are contained in a material for the gate electrode, side planes of n-type polycrystalline Si are etched by Cl radicals and Br radicals, and it is difficult to obtain the same manufactured shape as the p-type polycrystalline Si.

In manufacturing wiring materials such as TiN and Al—Cu alloys, a mixed gas of chlorine gas and boron chloride gas is used as the etching gas, and hydrocarbon gas and a hydrocarbon gas, of which hydrogen is partly substituted with fluorine, or nitrogen gas are added, in order to control its anisotropic manufacturing. Although these additive gases form a protective film against highly reactive Cl radicals, these additive gases cause a problem to grow shapes of isolated patterns.

In the process of oxide film etching, the etching characteristics are determined by CF₂, F, and ions in the plasma. (In plasma of CF group gas, CF, CF₃, C₂, and the like are existing in addition to CF₂. However, in the present specification, C, CF, CF₃, and the like are represented by CF radicals, and CF₂ radical is expressed as CF₂, and F radical is expressed as F.) More exactly, the etching characteristics depend on a generating amount of F and ions to CF₂ in the plasma. The reason is as follows:

Fluorocarbon gas introduced into an etching treatment chamber is dissociated to CF₂ radical, F radical, and ions in plasma, and injected into the wafer. Etching of the oxide film is proceeded by injecting ions onto planes whereon CF₂ and F are adhered. On the contrary, etching of resist or silicone nitride film is proceeded by F and ions, and CF₂ operates as an anti-etching film on the resist or the silicone nitride film by forming a polymer on their surface. Therefore, if the etching operation is performed under a condition wherein the injecting amounts of ions and F are smaller than that of CF₂, a high selection ratio to the resist or the silicone nitride film can be obtained. However, if the injecting amount of the ions is decreased, a problem that the etching velocity of the oxide film is decreased is generated. If the injecting amount of F is decreased, a problem that the etching process is terminated at holes having a high aspect ratio is generated. As explained above, the etching process is determined by the injection of CF₂, F, and ions, and, in particular, the etching process depends on the injecting amounts of ions and F to the injecting amount of CF₂. Accordingly, if the generating amount of F and ions to CF₂ in the plasma can be controlled independently, the process condition is extended, and as the result, finer and deeper manufacturing of the oxide film than ever becomes possible. Precisely, the etching velocity and selection ratio are influenced by the kind of the ions, but fundamentally, the etching process is determined by the amount of the F and the ions to the CF₂. When Ar diluting gas is used, almost of the partial pressure is based on the Ar gas, and almost of the ions are Ar ions. When the Ar diluting gas is not used, CF ions and C ions are injected. However, the amounts of the ions are 1/100-1/10 in comparison with the total amount of the radicals. The selectivity and the etching velocity are influenced by the kind of the ions, and an optimum generating amount of F to CF₂ is shifted sometimes approximately 10 percent.

Because the etching process is controlled by the mechanism explained above, a polymer is formed at the bottom of the contact hole with the CF radicals, and the etching process is terminated at a middle point, when the contact holes having a high aspect ratio are manufactured under an etching condition that F is less so as to obtain a high aspect ratio, because F becomes less at the bottom portion of the contact holes. On the contrary, in a case under a condition wherein a plenty of F and oxygen are supplied and the etching is not terminated, F and oxygen are supplied sufficiently to the bottom portion of the contact holes, and the etching process is proceeded. However, because the resist mask is etched with an excess of F and oxygen, the selection ratio to the resist can not be obtained sufficiently. Therefore, in accordance with the etching process to the contact holes explained above, an optimization of the injecting amount of ions and the injecting amount of F to the injecting amount of CF₂ is necessary.

However, in accordance with conventional etching apparatus, the yielding amounts of F, CF₂, and ions by dissociation of CF group etching gas are fixed, because a plasma density and an electronic temperature are fixed by determining an etching condition such as gas pressure, a high frequency power necessary for generating the plasma, and so on. Therefore, it has been difficult to change the generating amount of the ions with maintaining the generating amounts of F and CF₂ are constant, or to change the injecting amount of the F and CF₂ under a condition that the generating amounts of the ions is constant. For instance, in a case of a parallel plates type etching apparatus, the generating amount of the ions is increased by increasing a high frequency bias power for generating plasma, because the plasma density is increased. Simultaneously, the generating amount of F to CF₂ is also changed, because the dissociation by the plasma is proceeded.

Therefore, in accordance with the conventional art, the problem could not be solved, because the gas dissociation in the plasma was fixed, and the kinds, ratio, and generating amount of the radicals could not be controlled freely.

Additionally, when the contact holes having a high aspect ratio are etched under a condition wherein the gas pressure is as high as the prior art, the ions which should be injected perpendicularly into the wafer are collided with gas molecules, because the gas pressure is high, and a plenty of the ions are injected into the wafer in a slant direction. Therefore, the perpendicular manufacturing becomes difficult, because a part of the oxide film is manufactured in a lateral direction. The collision of the ions with the gas molecules can be prevented by decreasing the gas pressure, but in accordance with the conventional apparatus, if the gas pressure is decreased, the plasma density and the electronic temperature are changed. Accordingly, the decreasing the gas pressure has caused a problem that the ratio of F is increased, and a sufficient selection ratio to the resist and the nitride film can not be obtained.

In accordance with miniaturizing semiconductor devices, the etching process of the oxide film is required to be improved in preciseness of the manufacturing, and in the selection ratio to the nitride film (a nitride film selection ratio) and the selection ratio to the resist. In accordance with flattening the semiconductor device and increasing the multi-layered circuits, manufacturing the contact holes having a high depth/hole diameter ratio (aspect ratio) has been required.

The problem to be solved by the present invention is to realize manufacturing the oxide film, wherein a high selection ratio is required to the contact holes having a high aspect ratio and silicone nitride film, by controlling the generating amount of F and ions to CF₂ in plasma.

Furthermore, in manufacturing the gate electrode and the metallic circuit, the side etching by injecting Cl radicals and Br radicals into side planes of the pattern becomes a problem. The problem to be solved by the present invention includes an improvement in anisotropic manufacturing the gate electrode and the metallic circuit.

Furthermore, not restricted to the semiconductor wafer used for manufacturing the oxide film, the gate electrode, and the metallic circuit, the present invention is aimed at realizing the anisotropic manufacturing by readily setting, or controlling etching active species, the amount of the ions, and ratio, which are optimum for the manufacturing, to various substrates (members to be manufactured) including liquid crystal substrates, DVD substrates, glass substrates, and so on.

### SUMMARY OF THE INVENTION

In order to solve the above problems of the present invention, controlling and adjusting independently the generating amount of the radicals and the amount of the ions in the plasma are necessary. As a means therefor, the present invention sets an optimum electronic temperature region in the plasma. Or the present invention controls the electronic temperature region. The generating amounts of F and ions to CF₂ in plasma can be controlled independently by forming at least two plasma regions having different electronic temperature each other. In accordance with oxide film etching process using fluorocarbon gas, the generating amount of F to CF₂ is determined depending on the plasma temperature, and the generating amount of the ions are determined in proportional to the power introduced into the plasma generation. In a case of C₄F₈, the threshold energy for generating F from C₄F₈ is approximately 6 eV, but generation of CF₂ requires approximately 12 eV. Therefore, in a case when the electronic temperature is low (1-4 eV), F is readily formed, and a CF₂/F generating ratio becomes small.

When the electronic temperature is in the range of 5-20 eV, generation of CF₂ is enhanced, and the CF₂/F generating ratio becomes larger in comparison with the case of the low electronic temperature. Then, if two kinds of electronic temperature are used, it becomes possible to generate F and CF₂ at the high electronic temperature region, and to generate mainly F at the low temperature region. Accordingly, the generating amounts of F and CF₂ can be controlled or adjusted by setting appropriate values of the electronic temperature. In a condition wherein the values of the high and low electronic temperature are set, a CF₂/F ratio can be controlled by changing the areas of the two electronic temperature regions. The difference of these electronic temperature is at least 1 eV, preferably at least 5 eV. The two electronic temperature regions are spatially continued. The high electronic temperature region described hereinafter means a peak at the maximum value of the electronic temperature and its peripheral region, and a peripheral portion of a portion, wherein the electronic temperature becomes maximum, on a member to be treated or between the center in the member to be treated and a facing plane to the member to be treated. A position whereat the electronic temperature becomes an average value of the high electronic temperature and the low electronic temperature between the member to be treated and the facing plane to the member to be treated is defined as a boundary between the high electronic temperature region and the low electronic temperature region. If each of the low electronic temperature regions exists at both sides of the high electronic temperature region, a second boundary between the high electronic temperature region and the low electronic temperature region is defined additionally as same as the previous boundary. Here, the lowest electronic temperature in the second low electronic temperature region is equal to or somewhat higher than the lowest electronic temperature in the first low electronic temperature region.

In a case when two electronic temperature regions are formed such as the present invention, F is generated in both the two electronic temperature regions, and the ratio of CF₂/F is controlled in a condition where the total F exists excessively. The F can be eliminated selectively by adding a gas including hydrogen atom (such as H₂, CH₂F₂, CH₄ and so on) so as to react the F with H radicals. Furthermore, the F can be consumed by a reaction with inner wall materials. Practically, the inner wall of the etching apparatus is composed of the materials, which reacts with F, such as Si plate, SiC plate and the like, and F is eliminated by applying high frequency bias to the plates in order to enhance the consumption of F. Furthermore, the F can be eliminated by reacting with a polymer formed by adhering CF₂ onto the inner wall. If the wafer is placed closer to the inner wall portion, an injection fraction of F, which is generated by the plasma in the etching apparatus, into the inner wall is increased, because the area of the inner wall to the volume of the plasma is increased. That is, F can be eliminated effectively with reactions with the polymer by placing the wafer closer to the inner wall portion. Practically, a distance between the wafer and a plane facing to the wafer of the etching apparatus is shortened. In accordance with using the above means with the plasma having two kinds of electronic temperature, the ratio of CF₂/F becomes possible to be controlled in a wide range.

On the contrary, the generating amount of the ions is determined by the electronic density in the plasma, and the electronic density is approximately proportional to the high frequency input power. Individual radical (CF₂, F) is increased with increase of the high frequency power, but the generation ratio of CF₂/F scarcely depend on the high frequency power. Accordingly, making the two electronic temperature regions variable, the generating amount of the ions is maintained constant, and the generation ratio of CF₂/F can be controlled independently. Furthermore, the generating amount of CF₂ depends on the gas flow rate or partial pressure of fluorocarbon gas, and an injection ratio of CF₂/ions into the member to be treated can be controlled by the high frequency power in a condition wherein the dissociation of fluorocarbon to CF₂ is saturated.

### BRIEF DESCRIPTION OF THE DRAWINGS

FIG. 1 is a cross section of the dry etching apparatus using in the present invention, and a conceptual illustration indicating a formation of two kinds of electronic temperature regions of the present invention,

FIG. 2 is an illustration indicating a relationship between magnetic field intensity of ECR used in the present invention versus magnetic gradient and a thickness of the high electronic temperature region,

FIG. 3 is an illustration indicating a relationship between formation of two kinds of electronic temperature regions by controlling the magnetic gradient of the present invention versus the generation ratio of CF₂/F,

FIG. 4 is an illustration indicating a relationship of the distance between the member to be treated and a plane facing to the member to be treated of the present invention versus the generating amount of F and CF₂,

FIG. 5 is an illustration indicating a relationship of the distance between the member to be treated and the plane facing to the member to be treated of the present invention versus the injection ratio of CF₂/ions,

FIG. 6 is an illustration indicating a relationship between the high frequency (electromagnetic wave) (source) power applied for generating the plasma of the present invention versus the injection ratio of CF₂/ions onto the member to be treated,

FIG. 7 is an illustration indicating a relationship between the high frequency (electromagnetic wave) (source) power applied for generating the plasma of the present invention versus the ion current density on the member to be treated,

FIG. 8 is cross sections indicating the shapes of before manufacturing and after manufacturing the oxide film holes on the member to be treated using in the present invention,

FIG. 9 is a cross section of another dry etching apparatus using in the present invention,

FIG. 10 is a cross section of another dry etching apparatus using in the present invention,

FIG. 11 is cross sections indicating the shapes before manufacturing and after manufacturing on the member to be treated using in the present invention,

FIG. 12 is an illustration indicating the dependency of the injection ratio of CF₂/(F+0), and the injection ratio of CF₂/ions of the member to be treated on the C₄F₈ gas flow rate using for explanation of the present invention, and

FIG. 13 is an illustration indicating the dependency of the selection ratio at a shoulder portion of the silicone nitride film and the manufacturing shape (taper angle) on the C₄F₈ gas flow rate using for explanation of the present invention.

### DESCRIPTION OF THE PREFERRED EMBODIMENTS

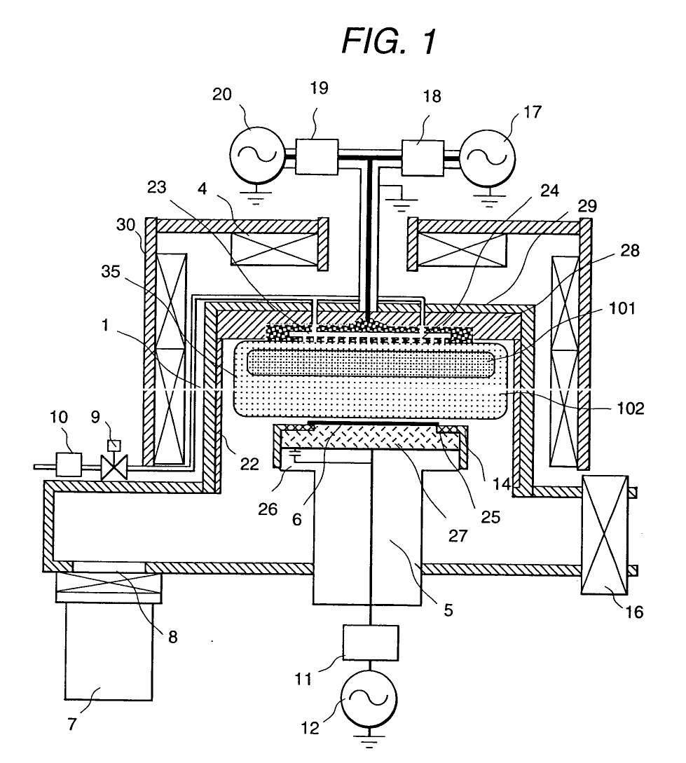

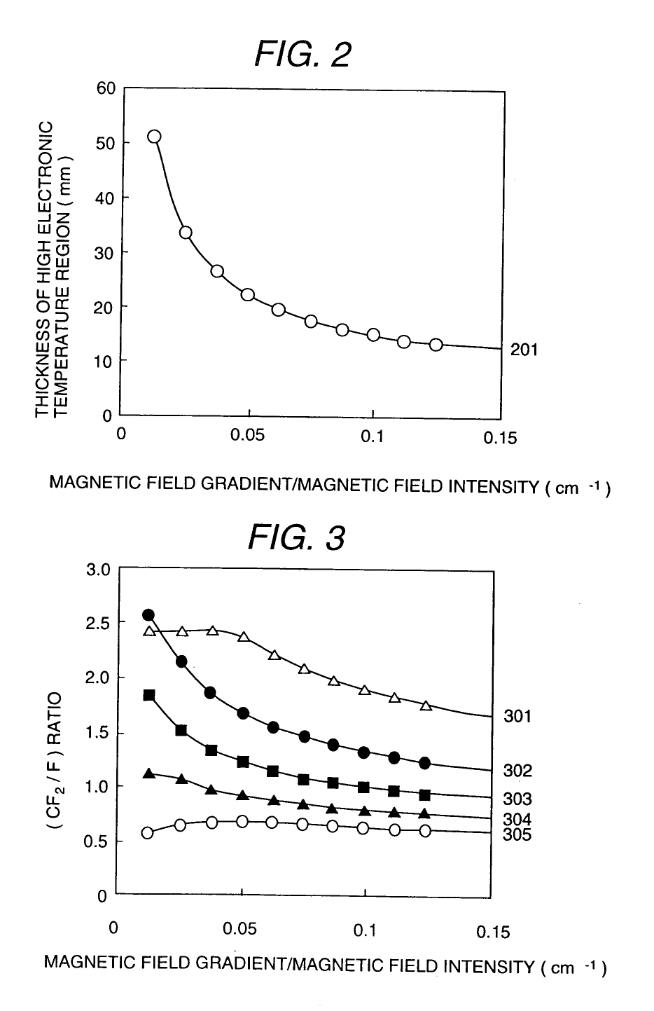

In accordance with a case when the etching apparatus using the electron-cyclotron resonance (ECR) as indicated in FIG. 1 as one of the practical methods for generating the two kinds of electronic temperature regions, the electronic temperature in the ECR region is high (a high electronic temperature region 101), and the low electronic temperature region 102 is formed in another region. An effective ECR region is a region having a magnetic field intensity with a definite width from the magnetic field intensity coinciding with the ECR condition. That is, the area of the ECR region having a high electronic temperature can be altered by changing the magnetic field gradient. The above status is indicated in FIG. 2. The magnetic field intensity satisfying the ECR condition varies depending on the frequency of the electromagnetic waves. Therefore, the abscissa of FIG. 2 was normalized by a ratio of the magnetic field intensity satisfying the ECR condition to the magnetic field gradient. As indicated in FIG. 2, the high electronic temperature region 201 becomes narrow when the magnetic field gradient of the magnetic field applied externally is increased, and the high electronic temperature region becomes wide when the magnetic field gradient of the magnetic field applied externally is decreased. Accordingly, the generation ratio of CF₂/F can be made variable by controlling the magnetic field gradient in the ECR region. As indicated by the curves 302, 303, and 304 in FIG. 3, the high electronic temperature region is extended by a condition when the magnetic field gradient is small, and the generation ratio of CF₂/F is increased. When the magnetic field gradient is increased, the high electronic temperature region is decreased, and the generation ratio of CF₂/F can be decreased. The curves 301 to 305 in FIG. 3 indicate an example when a gap between an antenna and the wafer is varied. The example will be explained later. When a ratio of magnetic field gradient/magnetic field intensity is at least 0.08/cm, change in the generation ratio of CF₂/F becomes small, because the low electronic temperature region becomes dominant. In particular, at least 0.15/cm, the generation ratio of CF₂/F is scarcely changed, and controlling the generation ratio of CF₂/F by the magnetic field gradient becomes difficult.

Furthermore, if the magnetic field gradient is constant, the ECR region is approximately inversely proportional to the frequency of the introduced electromagnetic waves. For instance, if the frequency is changed from 2.45 GHz to 450 MHz, the ECR region is extended by three times. Accordingly, the high electronic temperature region can be extended by lowering the frequency of the introduced electromagnetic waves, and the generation ratio of CF₂/F can be increased.

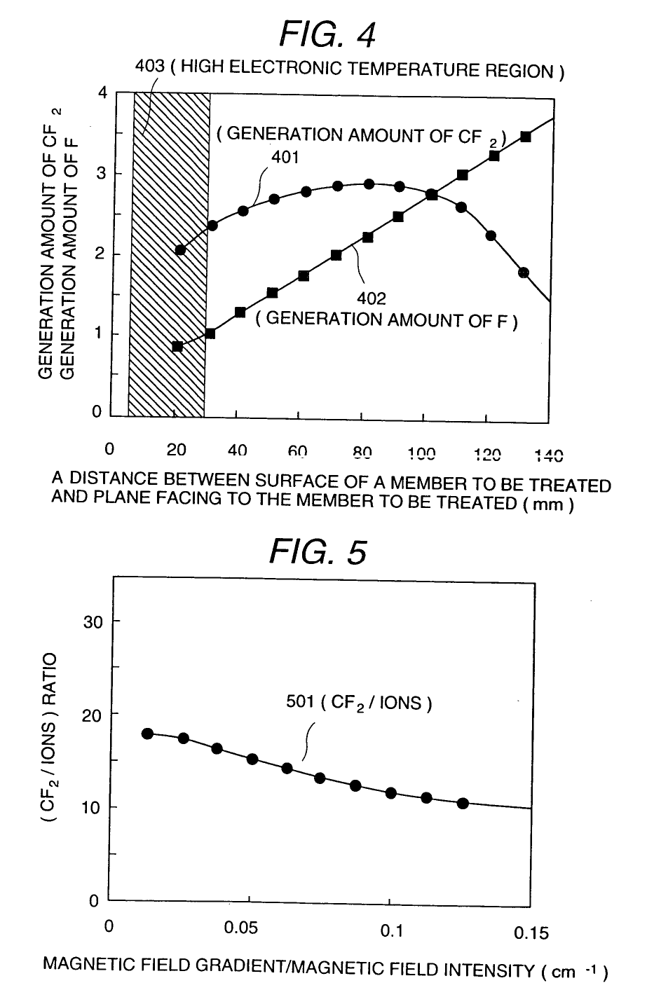

In a case when the magnetic field gradient is fixed (the high electronic temperature region is made definite) by fixing the frequency of the electromagnetic waves, the size of the low electronic temperature region 102 can be altered by changing the distance between the member to be treated 6 and the plane (the antenna 23) facing to the member to be treated. Here, the distance between the member to be treated and the facing plane is called as a gap, hereinafter. In FIG. 1, the facing plane is the antenna 23, but in general, the plane facing to the member to be treated 6 is a portion of the plasma processing chamber 35, and the member to be treated 6 is a plane contacting with the plasma and facing via the plasma. If the magnetic field gradient·magnetic field intensity are fixed at 0.03/cm, and the gap is made broadened, the generating amount of F (the curve 402) is increased as indicated in FIG. 4, because the low electronic temperature region is increased. On the contrary, the generating amount of the CF₂ (the curve 401) is increased with broadening the gap, but decreased if the gap is exceeded 100 mm. The decrement is caused by loss of the once dissociated CF₂ by recombination, because the distance whereby the once generated CF₂ in the ECR region reaches the member to be treated is extended. As explained above, if the gap is broadened, the generation ratio of CF₂/F is decreased. Therefore, the generation ratio of CF₂/F can also be controlled by the gap.

The generation ratio of CF₂/F can be controlled in a wide range by controlling both the magnetic field gradient and the gap, simultaneously. Dependency of the generation ratio of CF₂/F on the magnetic field gradient at the gaps of 20 mm, 40 mm, 70 mm, 100 mm, and 120 mm are indicated in FIG. 3. The abscissa of FIG. 3 indicates the magnetic field gradient divided by the ECR magnetic field intensity, and each of the marks 301 to 305 corresponds to the gap from 20 mm to 120 mm, respectively.

The generation ratio of CF₂/F becomes constant at the low magnetic field gradient side (equal to or less than 0.05/cm) of the gap of 20 mm (the curve 301), because the space in the gap becomes only the high electronic temperature region. When the gap exceeds 100 mm, the generation ratio of CF₂/F becomes not to be dependent on the magnetic field gradient, because the fluorocarbon is dissociated completely as indicated by the curve 305. When the gap is 20 mm, the plasma space is too narrow, and a pressure difference is generated at the central portion from the peripheral portion of the member to be treated. That means, the pressure on the member to be treated is fluctuated, and an uniform manufacturing becomes difficult.

In oxide film etching process, not only the generation ratio of CF₂/F, but also the injecting amount of CF₂ which becomes an etching protecting film against ion spattering, and the injecting amount of ions which generate ion spattering must be controlled, in order to obtain the selectivity for the resist film and the silicone nitride film. Dependency of the injection ratio of CF₂/ions to the member to be treated on the magnetic field gradient at the gap of 50 mm is indicated in FIG. 5. When the magnetic field gradient is increased, the high electronic temperature region is decreased, and the injection ratio of CF₂/ions is slightly decreased. The curve 501 indicates that the injection ratio of CF₂/ions can be controlled in the range of approximately 35% by the magnetic field gradient. When the magnetic field gradient is increased, the generating amount of CF₂ is decreased. In a case of large magnetic field gradient, the magnetic lines of force become divergent. However, the ions generated in the high electronic temperature region move along the magnetic lines of force, and the number of the ions, which are not injected into the member to be treated but escape around the member to be treated, is increased. Therefore, a large difference can not be observed in the injection ratio of CF₂/ions.

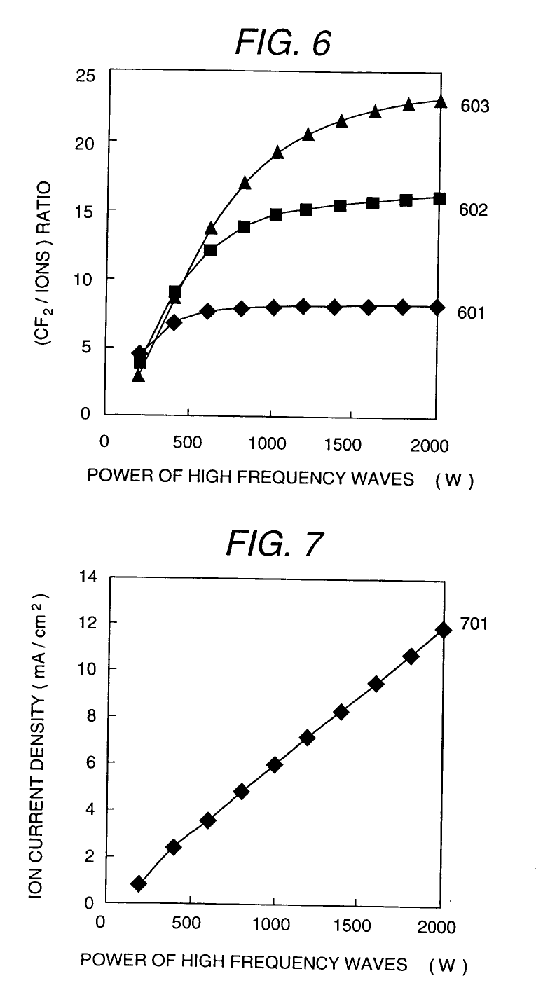

The generating amount of CF₂ depends not only on the electronic temperature and the electronic density, but also on the gas flow rate of the fluorocarbon gas. In a case when the gas flow rate is 10 ml/min (the curve 601) as indicated in FIG. 6, the injection ratio of CF₂/ions on the member to be treated is saturated at approximately 8, but with 20 ml/min (the curve 602) or 30 ml/min (the curve 603), the saturated value of the injection ratio of CF₂/ions becomes approximately 16 or 23, respectively. Because the ion current density does not depend on the gas flow rate, the generating amount of CF₂ can be controlled by the gas flow rate, and the ion current density can be controlled by the high frequency power. Therefore, the injection ratio of CF₂/ions can be set in accordance with the process.

For instance, in accordance with FIG. 6, the injection ratio of CF₂/ions can be varied approximately from 8 to 20 by altering the gas flow rate in the range of 10-30 ml/min with the high frequency power of 1000 W. Accordingly, the injection ratio of CF₂/ions can be controlled in a wide range by controlling with a combination of the magnetic field gradient and the gas flow rate.

The electronic density in plasma is approximately proportional to the high frequency power (this is an input power from a high frequency power source generating electromagnetic waves, but simply called as high frequency power, here), and the injection amount of the ions on the member to be treated (ion current density) is also proportional to the high frequency power. As indicated by the curve 701 in FIG. 7, the ion current density is increased approximately in proportional to the high frequency power. The etching velocity of the oxide film is approximately proportional to the ion current density. Therefore, in order to perform a quick etching, an ion current of at least 5 mA/cm² is necessary. Furthermore, as described previously, the ion current density is decreased by broadening the gap. Therefore, the high frequency power must be increased, in order to obtain the same ion current density as before when the gap is broadened.

As explained above in a case of the ECR etching apparatus, the generation ratio of CF₂/F can be controlled independently from the generating amount of the ions by controlling the position of the ECR, magnetic field gradient, frequency of introduced electromagnetic wave, distance between the member to be treated and a plane facing to the member to be treated, and gas flow rate.

In manufacturing the gate electrode and the metallic circuit, generation of Cl radicals and Br radicals can be suppressed by controlling the two electronic temperature regions. The dissociation of Cl₂ to Cl requires a dissociation energy of 2.5 eV, and the dissociation of HBr to Br requires a dissociation energy of 3.8 eV. Accordingly, the generating amount of Cl radicals and Br radicals can be suppressed in the low electronic temperature region having an electronic temperature lower than the dissociation energy, because generating amount of the radicals is small and recombination of the radicals is generated.

In accordance with decreasing the generating amount of Cl and Br, side etching at side planes of the gate electrode and the metallic circuit can be suppressed. The ions are generated mainly in the high electronic temperature region, and the generating amount of the ions can be controlled independently from Cl and Br. Hitherto, the oxide film etching method has been explained particularly among the manufacturing methods of the member to be treated on the semiconductor device by dry etching. However, the etching method of the present invention can be applied not only to manufacturing the semiconductor device, but also to fine manufacturing using dry etching apparatus for liquid crystal, TFT, DVD disk, DVD head, magnetic head, and so on.

The embodiment using the apparatus indicated in FIG. 1 is explained in details, hereinafter. The apparatus comprises an etching treatment chamber 1 composed of a vacuum chamber 30, which is an external cylinder of the process chamber itself, and an internal cylinder 22. The internal of the etching treatment chamber 1 comprises a plasma treating chamber 35, an antenna 23, an antenna dielectric body 28, and a treating plate 5. An etching gas (treating gas) is introduced into the plasma treating chamber 35 through an gas inlet 24 provided at the antenna 23, and plasma is generated by introducing electromagnetic waves of 300 MHz to 600 MHz generated by a high frequency power source 17 via a matching box 18 through the antenna 23 into the plasma treating chamber 35. As the etching gas, CF group gas is preferably used for the etching of insulating film such as silicone oxide film and the like. In order to propagate the electromagnetic waves to the plasma treating chamber 35 effectively, an outer diameter of the antenna 23 and size and material of the antenna dielectric body 28 are determined so as to make the electromagnetic waves resonate between the antenna 23 and an antenna earth 29 with a desired mode (here, TM01).

The electromagnetic waves resonate between the antenna 23 and the antenna earth 29, and the electromagnetic waves are propagated to the plasma treating chamber 35 via peripheral portions of the antenna dielectric 28. In order to discharge effectively, three solenoid coils 4 for generating magnetic field contained in a coil case 30, respectively, are arranged in yoke 21 at peripheral portion of the etching treatment chamber, and a coil current is set in order to form a magnetic field between 0 to 320 Gauss at approximately above the process platform. Then, high density plasma having an electronic density of at least 10¹¹ electrons/cm³ is generated using electron-cyclotron resonance. The process platform 5 are provided in the plasma treating chamber 35. A member to be treated 6 is placed on the process platform, and etched with the gas plasma. The member to be treated 6 is transferred into the etching treatment chamber 1 through a valve 16. The etching gas is introduced into the plasma treating chamber 35 through a gas flow controller 10 and a valve 9, and exhausted outside the plasma treating chamber 35 through an exhaust valve 8 by an exhaust pump 7. The pressure in the plasma treating chamber 35 is controlled to be a designated value by a conductance valve 8 provided on the top of the exhaust pump 7. An inner cylinder 22 is arranged on the side wall of the plasma treating chamber 35, in order to control accumulation of reaction products and to save clean up operation time by changing components at clean up operation. The process platform 5, whereon the member to be treated (the member to be treated 6 in the embodiment of the present invention is a wafer. Then, the member to be treated and the wafer are used in the same meaning) is placed, is provided with a high frequency power source 12 and a matching box 11, which can supply high frequency bias from 400 kHz to 13.56 MHz to the electrode 27. The position of the process platform 5 can be set with a distance in the range of 20 mm to 150 mm from the antenna 23. The periphery of the process platform 5 has a structure, wherein a focus ring 25 having a width of approximately 30 mm can be arranged surrounding the wafer, and the high frequency waves applied to the wafer 6 are partly, approximately 10% to 20%, applied to the focus ring 25 by branching with a condenser 26 (it may not be an electronic component, but it may be formed by forming a dielectric film and the like on surface of the high frequency bias applying portion 27). The mark 14 indicates a suscepter. The material of the focus ring 25 is single crystal silicon, and impurity doped Si or SiC can be provided. The suscepter 14 composed of insulating material such as alumina and the like is arranged at periphery of the focus ring 25 and the high frequency bias applying portion 27 for preventing wafer bias from leaking to periphery, and preventing the high frequency bias applying portion 27 from being damaged by plasma. A high frequency power source 20 is connected to the antenna 23 via a high frequency filter 19 provided with a stab tuner 18 and a filter circuit, in order to apply high frequency having different frequency (10 kHz to 27 MHz) from the high frequency power source to supply electromagnetic waves to the antenna 23. The material of the antenna 23 is impurity doped Si at the plasma treating chamber side, and Al at its opposite side.

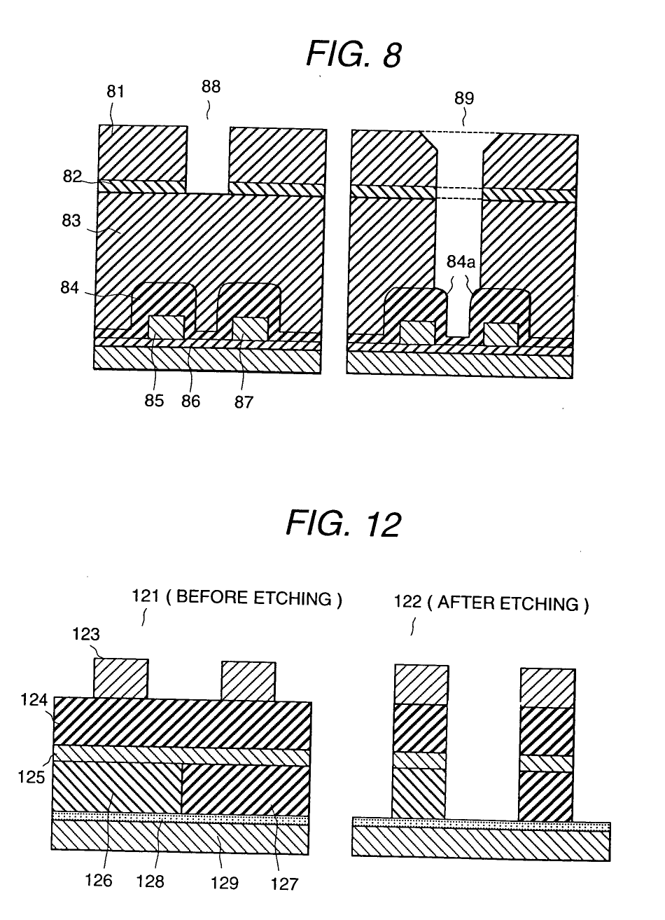

As the member to be treated 6, eight inches silicone wafer having the structure indicated in FIG. 8 formed on its surface is transferred from an adjacent transfer chamber (not shown in the figure) via a gate valve 16. The wafer 88 before etching is composed of a silicone wafer 87 having a gate oxide film 86 of 4 nm thick formed thereon, and a gate electrode 85 of 300 nm thick and 80 nm wide composed of polycrystalline Si and W formed on a part of the surface of the gate oxide film. Silicone nitride film 84 of 200 nm thick is formed on the upper surface of the gate electrode, and silicone nitride film 84 of 60 nm thick is formed on the side surface of the gate electrode and the upper surface of the gate oxide film so as to cover the gate electrode 85. An oxide film 83 (SOG and CVD oxide film) of 1600 nm thick (at the most thick portion) is formed on the upper surface of the silicone nitride film. Above the film, a reflection preventing film 82 of 80 nm thick and a resist mask 81, whereon a hole pattern of 130 nm in diameter is exposed and developed, of 500 nm thick are formed. The width of the oxide film 83 existing between the gate electrode is approximately 60 nm.

In accordance with FIG. 1, a mixed gas consisting of Ar 800 ml/min, C₅F₈ 20 ml/min, and O₁ 20 ml/min, is introduced into the plasma treating chamber 35 through the gas inlet 24, and pressure of the gas is maintained at 2.5 Pa. Gas plasma is generated by applying electromagnetic waves of 450 MHz, 1.3 kW, and the oxide film is etched by applying bias of 2 MHz, 1000 W to the process platform 5. The height of the process platform is adjusted so as to make the distance (gap) from the wafer surface to the antenna 23, which is the facing plane to the wafer, to be 50 mm. The coil current is adjusted to make the magnetic field intensity 160 Gauss at a position far from the wafer 6 by 35 mm on the central portion of the wafer and a position far from the wafer 6 by 50 mm at the surrounding of the wafer, and to make the magnetic field gradient 12 gauss/cm at the same positions (ECR height). The magnetic field intensity of 160 gauss is a magnetic field intensity to satisfy the ECR condition, because the frequency of the electromagnetic waves applied to the antenna 23 was set as 450 MHz in the present embodiment. Under the above condition, the thickness of the ECR region is approximately 17 mm, and the region can be regarded as the high electronic temperature region 101. The electronic temperature is approximately 8 eV. Furthermore, high frequency bias of 13.56 MHz is applied to the antenna 23 by 300 W. The electronic temperature in the low electronic temperature region 102 corresponding to the region other than the ECR region is approximately 2 eV. The generation ratio of CF₂/F by dissociation of C₅F₈ becomes approximately 1.5. However, the injecting amount of F into the wafer 6 is actually decreased by a reaction with the polymer (organic group accumulated compounds such as etching gas, reaction products, and so on) on the surface of the antenna 23 corresponding to the plane facing to the wafer, and consumption of F by Si on the surface of the antenna 23 with applied bias from the high frequency power source 20 to the antenna 23. Therefore, the injection ratio of CF₂/F into the wafer becomes approximately 12. As explained above, the high electronic temperature region 101 corresponding to the ECR region, and the low electronic temperature region 102 are formed by setting the gap between the wafer 6 and the antenna 23, the ECR height, and the magnetic field gradient. As the result, the CF₂/F ratio corresponding to two kinds of electronic temperature regions could be obtained. Naturally, the CF₂/F ratio is readily variable by controlling the current value of the coil 4 to change the magnetic field gradient. The injection ratio of CF₂/ions into the wafer 6 is readily variable by controlling the input power of the electromagnetic waves, that is, the power from the high frequency power source 20, because the ion current can be changed readily by controlling the power. In accordance with the present embodiment, a method to consume F with the surface of the antenna 23 composed of Si by applying high frequency bias having a frequency different from the electromagnetic waves of 450 MHz from the high frequency power source 20 to the antenna 23 in order to control the CF₂/F ratio has been indicated. However, it is needless to say that the above method is not necessarily the substantial method for controlling the CF₂/F ratio.

The CF₂/F ratio has been set by the above method. However, unnecessary C from C₅F₈ is injected into the wafer in a form of C₂ or C radicals. Consequently, an accumulated film composed of c is formed on the surface of the wafer 6, and the film disturbs proceeding the etching. Accordingly, it becomes necessary to add O₂ in order to eliminate the accumulated film in the present process.

Main etching conditions can be determined by the above setting. Next, if the input power of the electromagnetic waves is assumed to be 1000 W, the ion current density becomes approximately 5 MA/cm². Under the above condition, the oxide film hole of 100 nm in diameter was etched. Then, the etching velocity of 500 nm/min, and the selection ratio of 8 to the resist were obtained.

Next, the oxide film etching was performed on a self-align contact (SAC) structure indicated in FIG. 8. FIG. 8(a) indicates a cross section of the wafer before etching, and FIG. 8(b) indicates a cross section of the wafer after etching. The result is indicated as the shape 89 after etching. After starting the etching, the silicone nitride film begins to be appeared after approximately 145 seconds. Subsequently, the etching process is finished after approximately 200 seconds. Generally, the shoulder portion 84a (at a corner portion of either right or left upper portion of the gate electrode) of the silicone nitride film 84 is readily reduced, and increasing the selection ratio at the shoulder portion 84a of the silicone nitride film 84 and the oxide film 83 is extremely difficult. However, in accordance with the condition of the present embodiment, a relatively high value, such as approximately 20, was obtained for the selection ratio of the reduction at the shoulder portion 84a of the silicone nitride film 84.

How etching characteristics may change when the CF₂/F ratio has been altered is as follows:

For instance, in a case when the magnetic field gradient is 4 Gauss/cm, the resist selectivity is very high, the silicone nitride film is hardly reduced, and extremely high selection ratio can be obtained. However, the etching process is terminated after approximately 145 seconds due to the lack of F. The selection ratio can be controlled by adjusting the magnetic field gradient as explained above, but in order to perform the etching process practically, it is necessary to set an optimum condition.

In order to utilize the etching method of the present invention more effectively, changing the magnetic field gradient in the middle of the etching process is effective. The etching process is proceeded with the magnetic field gradient of 4 Gauss/cm, which makes it possible to take a large selection ratio, during 170 seconds from the starting point of the etching process; after 170 seconds to 190 seconds, the magnetic field gradient is adjusted to 8 Gauss/cm, which makes it possible to maintain the etching process and to ensure the somewhat desirable selection ratio; and after 190 seconds to 200 seconds, the magnetic field gradient is adjusted to 12 Gauss/cm, which makes it possible to proceed the etching to the bottom of the SAC holes. In the above case, the reducing amount of the silicone nitride film 84 can be suppressed at minimum, and the selection ratio to the shoulder portion of the silicone nitride film can be approximately 30.

The embodiment, wherein the magnetic field gradient is altered in the middle of the etching process for controlling the high electronic temperature region 101 and the low electronic temperature region 102 in order to optimize the CF₂/F ratio, has been indicated above. However, the substantial point of the present invention is in optimizing the CF₂/F ratio during the etching process. That means, instead of adjusting the magnetic field gradient, the ECR height may be changed. The gas, gas flow rate, and input power of the electromagnetic waves are similar.

The adjusting range of the magnetic field gradient is restricted by an arrangement of the coil 4, and a range of the current. However, when the ECR magnetic field intensity of 160 Gauss in a case when 450 MHz is introduced into the antenna 23 is taken as a standard, the adjusting range may be the range from 1.6 Gauss/cm to 24 Gauss/cm. That is, the magnetic field gradient/ECR magnetic field gradient is taken in the range from 0.15/cm to 0.01/cm.

Next, how the etching characteristics is changed with variation in injecting amount of F into the wafer, that is the member to be treated 6, will be explained, and the importance of controlling CF₂, F by the present invention will be indicated.

The etching characteristics was studied, in a case when the gap and the ECR height were maintained at constant, and the magnetic field gradient was fixed at 8 Gauss/cm; under the above condition, the amount of F was changed by applying a bias to the antenna 23 for controlling the reaction of F with Si at the surface of the antenna. When the power of the high frequency power source 20 is decreased from 300 W to 200 W in order to change the bias applied to the antenna 23, the consuming amount of F at the antenna is decreased. As the result, the reaching depth in the hole manufacturing becomes as same as the case of 12 Gauss/cm, and the selection ratio to the shoulder portion of the silicone nitride film becomes approximately 20. Furthermore, when the power of the high frequency power source 20 is changed to 100 W, the reaching depth of the hole becomes deeper, but a sufficient shoulder selection ratio can not be obtained. If the power of the high frequency power source 20 is further decreased, accumulated materials are adhered onto the surface of the antenna, and stable etching process becomes difficult. In accordance with the above result, it is revealed that the reaching depth of the etching hole becomes deeper by increasing the CF₂/F ratio, but the selection ratio of the silicone nitride and the oxide film is decreased. On the contrary, when the CF₂/F ratio is decreased, that is, in a case when F is decreased, improvement in the selection ratio can be expected. If the power of the high frequency power source 20 is increased to 800 W, the consumption of F is further increased, the resist selection ratio is increased, and the selection ratio of the silicone nitride film is increased to approximately 30, but etching residue is generated. In order to solve the above problem, the power of the high frequency power source 20 is maintained at 800 W, and the flow rate of O₂ is changed to 23 ml/min. Then, the etching residue is eliminated, but the selection ratio of the silicone nitride film is decreased to approximately 23. If the power of the high frequency power source 20 is further increased, a consuming effect of F can be observed. However, when the power exceeds 1000 W, the reaction at the surface of the antenna becomes active, and the reaction products are adhered to the surface of the wafer as the etching residue. Accordingly, setting the CF₂/F ratio in an appropriate range is important to ensure the desirable etching depth and the selection ratio.

Next, effects of the gap on the etching characteristics are indicated.

Under the etching condition described above, the power of the high frequency power source 20 is maintained at 300 W, and the magnetic field gradient is set at 4 Gauss/cm, and the gap is broadened from 50 mm to 90 mm. Then, on the contrary to the case of gap of 50 mm, wherein the sufficient etching depth could not be obtained due to the lack of F, the problem of etching stop was solved, because F was increased with increasing the high electronic temperature region 101 by decreasing the magnetic field gradient, and increasing the low electronic temperature region 102 by broadening the gap. The selection ratio at the shoulder portion of the silicone nitride film in the above case was approximately 20.

Furthermore, when the gap is broadened to exceed 100 mm, C₅F₈ is dissociated excessively, and C, F radicals become excess. Therefore, the etching stop is generated, and sufficient selectivity can not be obtained, even if radical control is performed with the magnetic field gradient. On the contrary, when the gap is shortened to less than 30 mm, the gap becomes as almost same as the ECR region, and only the high electronic temperature region 101 is formed. Therefore, the dissociation control by the magnetic field gradient becomes difficult. Furthermore, the gas supplied from the gas inlet 24 flows through a narrow space between the wafer 6 and the antenna 23. Therefore, a pressure distribution is generated on the surface of the wafer, and uniform manufacturing becomes difficult. As described above, the areas of the high electronic temperature region 101 and the low electronic temperature region 102 can be altered by setting the gap between the wafer 6 and the antenna 23 in the range of 30 mm to 100 mm, and as the result, adjustment of the CF₂/F ratio becomes possible. In accordance with the present embodiment, the gap between the wafer 6 and the antenna 23 was explained, but the gap between the wafer 6 and the plane facing to the wafer is similar, and the gap is not restricted to between the antenna and the wafer.

Next, an adequate pressure range in the present invention is explained. Generally, if the pressure is low, the energy obtained by an electron, during being accelerated by electromagnetic waves until collided with other gas molecule, becomes large. That is, the electronic temperature tends to be higher. Physical meaning of the present invention lies in controlling the electronic temperature and its region, and controlling the dissociation of gas molecules. Therefore, the pressure range has an important meaning. However, because the dissociation energy of gas molecule differs depending on the kind of the gas molecule, the adequate electronic temperature and pressure range differ depending on the kind of the etching gas.

When Ar gas flow rate is set as 400 ml/min and gas pressure is set as 0.1 Pa, the electronic temperature in the low electronic temperature region 102 becomes high as 2.8 eV. When etching treatment is performed under the condition of oxygen flow rate 5 ml/min, gap 50 mm, and magnetic field gradient 4 Gauss/cm, the selection ratio at the shoulder portion of the silicone nitride is approximately 18. Furthermore, when the gas pressure is decreased to lower than 0.1 Pa, the electronic temperature in the low electronic temperature region 102 is increased rapidly, and control of the CF₂/F ratio by the magnetic field gradient becomes difficult. When influence of the gas pressure is studied in view of the resist selection ratio, it is revealed that the resist selection ratio is approximately 8 with the gas pressure in the range from 2.5 Pa to 1.5 Pa, but the resist selection ratio is decreased to approximately 6 at the gas pressure of 0.5 Pa, and the resist selection ratio is decreased to approximately 5 when the gas pressure is decreased to 0.1 Pa. Based on necessity to keep the selection ratio high, the gas pressure must be at least 0.1 Pa. In accordance with the above reason, the lower limit of the gas pressure is approximately 0.1 Pa, when the etching process is performed with CF group gas. When the gas pressure is set at 4 Pa, retention time of the gas becomes longer in comparison with a case of lower pressure, and injection amount of the reaction products into the wafer 6 is increased. Therefore, accumulative adhered substance tends to be formed on the surface of the wafer 6, and under the condition of magnetic field gradient 12 Gauss/cm, gap 50 mm, power of the high frequency power source 20 of 300 W, the etching residue is generated at the bottom of the hole. The etching residue was disappeared by decreasing the power of the high frequency power source 20 from 300 W to 150 W to suppress the consuming amount of F, in order to eliminate the accumulative adhered substance with F. When the gas pressure is further increased to 6 Pa, the gas retention time is extended, and the etching residue is readily generated. However, if Ar flow rate is increased to 1200 ml/min, the gas retention time becomes as same as the case of 4 Pa, and similar etching depth can be obtained. If the gas pressure is further increased, slant injection of the ions are increased, and obtaining perpendicularly manufactured shapes becomes difficult. Furthermore, control of plasma composition becomes difficult due to dissociation of the reaction product (mainly, reaction product of the resist), even if the generation ratio of CF₂/F in the etching gas is controlled by the magnetic field gradient. Because of the reason described above, the upper limit of gas pressure in the etching process with the CF group gas is 4 Pa. Influence of the gas pressure when the manufacturing dimension becomes more precise was further studied. The hole diameter of 130 nm, from which the above results have been obtained, is decreased to 100 nm. Then, obtaining a sufficient etching velocity in the hole becomes difficult with 4 Pa, even if the oxygen flow rate is increased. However, if the gas pressure is decreased to equal to or lower than 3 Pa, the similar etching process with the case of the hole diameter of 130 nm becomes possible. In a case when the hole diameter is further small as 80 nm, the gas pressure may further be decreased to equal to or lower than 2.5 Pa. As explained above, it has been revealed that decreasing the gas pressure is an effective countermeasure to correspond to increasing preciseness of the manufacturing dimension. The pressure range of the present invention from the lower pressure limit of 0.1 Pa to the upper pressure limit of 4 Pa can sufficiently correspond to the requirement.

As described above, the CF₂/F ratio can be varied by controlling the magnetic field gradient, even if the ion current is maintained at a definite value. By decreasing the magnetic field gradient, the selection ratio to the resist can be increased. However, decreasing the magnetic field gradient means decreasing difference of the magnetic intensity at various portions, and also means forming an uniform magnetic field in the etching apparatus. In order to realize the above condition, it is necessary to provide many coils around the etching apparatus. If the magnetic field intensity to satisfy the ECR condition is decreased, the magnetic field gradient to satisfy effectively the ECR condition is decreased in proportional to the magnetic field intensity, and the magnetic field gradient can readily be controlled. Because the magnetic field intensity to satisfy the ECR condition is determined by the frequency of the electromagnetic waves for generating plasma, lowering the frequency of the electromagnetic waves is advantageous in coil designing and cost down of the apparatus. In accordance with the present embodiment, the frequency of the electromagnetic waves was taken in the range of 300 MHz to 600 MHz in consideration of easiness of plasma start, the electronic temperature of the plasma generated in the ECR region, and others, in addition to the above features.

In accordance with the above embodiments, the cases of Ar/C₅F₈/O₂ as the etching gas are indicated. However, even if any one of the CF group gases such as C₄F₈, C₄F₆, C₃F₆, and C₃F₈ is used as the etching gas, approximately the similar result can be obtained, except the optimum flow rate of oxygen. Approximately similar result can be obtained, even if any one of SF₆, CF₄, and SiF₄ is used instead of oxygen. Furthermore, the selectivity to the resist can be increased by addition of any one of SiH₂F₂, SiH₄, and CO gas.

The similar result can be obtained by using the high frequency bias applied to the antenna 23 for controlling F by branching from the high frequency power source 12, which applies the bias to the wafer 6. When branching, it is effective if phases of the high frequency bias applied to the antenna 23 are shifted by approximately 90 degrees from the phases of the high frequency bias applied to the wafer 6.

If any insulating film such as glass materials containing boron, or phosphorus (BPSG, PSG), silicone glass containing organic substance (organic SOG), and oxide film containing F, is used as the material for the oxide film, i.e. the film to be etched, the similar results can be obtained.

Next, another embodiment using the apparatus indicated in FIG. 1 is explained.

Eight inches silicone wafer is transferred into the apparatus as the member to be treated. On the silicone wafer, a silicone nitride film of 0.1 μm thick is formed, an oxide film of 1.5 μm thick is formed thereon, and a resist mask reprinted with a mask pattern is formed thereon. Holes having 150 nm in diameter are formed on the resist mask.

In accordance with the apparatus indicated in FIG. 1, a mixed gas consisting of Ar 200 ml/min, and C₄F₈ 10 ml/min is introduced into the plasma treating chamber 35 through the gas inlet 24, and pressure of the gas is maintained at 1 Pa. Gas plasma is generated by applying electromagnetic waves of 450 MHz, 1 kW, and the oxide film is etched by applying bias of 800 kHz, 800 W to the process platform 5. The process platform is positioned by 60 mm from the antenna 23, and the coil current is adjusted to make the magnetic field intensity 160 Gauss at a position above the wafer 6 by 40 mm, and to make the magnetic field gradient 4 gauss/cm at the same positions (ECR height). Under the above condition, the thickness of the ECR region is approximately 35 mm, which can be regarded as the high electronic temperature region 101, and the electronic temperature is approximately 8 eV. The electronic temperature in the low electronic temperature region 102 corresponding to the region other than the ECR region is approximately 2 eV. The generation ratio of CF₂/F by dissociation of C₄F₈ becomes approximately 1.0. However, the actual injecting amount of F into the wafer 6 is further decreased by consumption on the surface of the antenna 23. Therefore, the injection ratio of CF₂/F into the wafer becomes approximately 3. The ion current density becomes approximately 5 mA/cm². Under the above condition, the etching velocity of the oxide film is approximately 500 nm/min, selection ratio to the resist is 20, and the selection ratio to the nitride film of substrate is 30.

How deep the etching process can be performed was studied by increasing the thickness of the oxide film to 3 μm, maintaining the contact hole diameter as 150 nm. As the result, the etching process was terminated at the depth of 2 μm. In accordance with the prior art, termination of the etching process in this case must be prevented by adding oxygen gas, in order to eliminate the accumulated substance at the bottom of the hole. However, when the oxygen is added, the selection ratio of the resist is decreased to approximately 5. On the contrary, in accordance with the present invention, if the generation amount of F is increased by increasing the magnetic field gradient from 4 Gauss/cm to 10 Gauss/cm, the etching process for the oxide film of 3 μm thick and the contact hole of 150 nm in diameter is not terminated at middle of the process, and approximately perpendicularly manufactured shape can be obtained. In this case, the selection ratio to the resist is decreased to approximately 10, but the selection ratio is larger in comparison with the case of oxygen addition.

As explained above, corresponding to various etching conditions becomes easy by changing the magnetic field gradient for controlling the CF₂/F ratio, even if the gas condition is same, and the addition of oxygen and the like becomes unnecessary.

Another embodiment wherein the additive gas becomes unnecessary is indicated, hereinafter.

Under the same etching conditions such as the frequency of the electromagnetic waves applied to the antenna 23 is 450 MHz and the magnetic field gradient is 4 gauss/cm, the distance between the wafer 6 and the antenna 23 is changed from 60 mm to 100 mm, and manufacturing the patterned contact hole of 150 nm in diameter is performed on a silicone oxide film of 1.5 μm thick. The relative injection amount of F into the wafer 6 is increased by broadening the gap, because the low electronic temperature region 102 is increased and the influence of F consumption at the surface of the antenna 23 is decreased. Therefore, the selection ratios to the resist and the nitride film are decreased to 10 and 12, respectively. When the gap was equal to or more than 100 mm, any influence to the selection ratio was not observed. In addition to the above condition, if CH₂F₂ gas is added by approximately 5 ml/min, the selection ratio to the resist becomes 20, and the selection ratio to the nitride film becomes approximately 25. However, CH₂F₂ is a strongly accumulative, and adhered onto the inner wall. Therefore, frequency of cleaning is increased, and throughput is decreased. That is, decreasing the gap in order to improve the selection ratio is more advantageous in view of the throughput. However, if the gap is decreased to 40 mm, the injection amount of F is decreased, and the etching process is terminated at the depth of approximately 1.2 μm, even the selection ratio is increased. As explained above, the desired etching characteristics can be obtained by controlling the CF₂/F ratio with controlling the distance between the wafer 6 and the antenna 23, and the magnetic field gradient, without adding any gas. If oxygen is added, sufficiently satisfying etching characteristics can be obtained even if the gap is decreased to 30 mm.

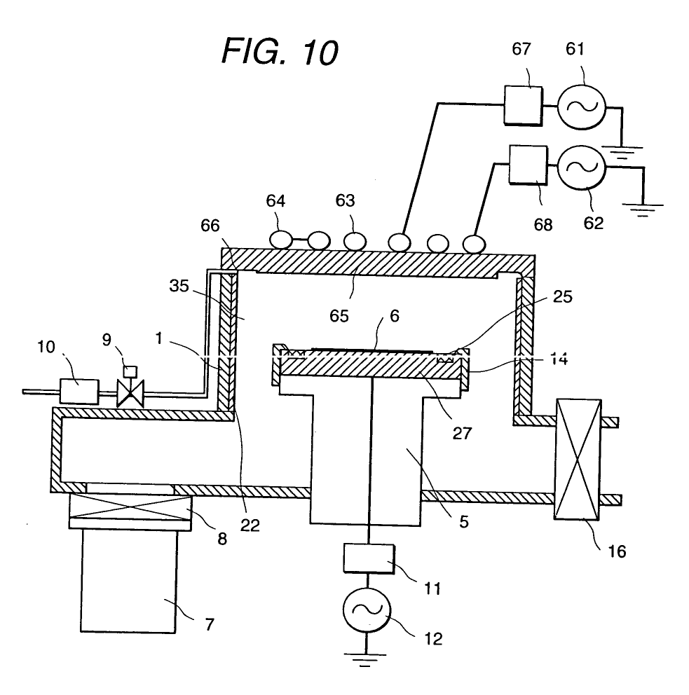

Next, another embodiment using the apparatus indicated in FIG. 10 is explained. The same numeral marks are designated to the same component in FIG. 10 as the components indicated in FIG. 1, and explanation is omitted. In accordance with the present apparatus, an etching gas is introduced into the plasma treating chamber 35; which is composed of a vacuum vessel 13, i.e. an external cylinder, and an inner cylinder 22; through the gas inlet 66, high frequency waves in the range of 10 MHz to 100 MHz are generated by a first high frequency power source 61 and a second high frequency power source 62, and gas plasma is generated by introducing the high frequency waves into the plasma treating chamber 35 through ring antennas 63, 64, and a wafer facing plane 65 composed of ceramic material. Each of matching boxes 67, 68, is provided to respective of the high frequency power sources 61, 62, in order to supply power effectively to the plasma. The plasma becomes high density plasma having an electron density of at least 10¹¹ electrons/cm³. The process platform 5 is provided in the plasma treating chamber 35, and the member to be treated 6 (wafer) is placed on the process platform and etched with gas plasma. The etching gas is introduced into the plasma treating chamber 35 through the gas flow rate controller 10 and the valve 9, and exhausted outside the etching treatment chamber 1 by the exhaust pump 7. The process platform 5, whereon the member to be treated 6 is placed, is provided with the high frequency power source 12 and matching box 11, and high frequency bias from 400 kHz to 13.56 MHz can be applied. The wafer facing plane 65 is made of a ceramic material composed of Si 50% and SiC 50%. An elevator is provided to the process platform 5, in order to make it possible to adjust the distance between the wafer 6 and the wafer facing plane 65 in the range from 20 mm to 150 mm. Desirably, the distance between the process platform 5 and the wafer facing plane 65 in the range from 30 mm to 100 mm is adoptable. The same numeral marks are designated to the same component having the same function in FIG. 10 as the components indicated in FIG. 1, and explanation in details is omitted.

Eight inches silicone wafer is transferred into the apparatus as the member to be treated. On the silicone wafer, an oxide film of 2 μm thick is formed, and a resist mask reprinted with a mask pattern is formed thereon. Holes having 200 nm in diameter are formed on the resist mask.

In accordance with the apparatus, a mixed gas consisting of Ar 30 ml/min, and C₃F₈ 20 ml/min, H₂ 8 ml/min is introduced into the etching treatment chamber 1 through the gas inlet 24, and pressure of the gas is maintained at 0.7 Pa. The process platform 5 is adjusted so that the distance from the wafer 6 to the wafer facing plane 65 becomes 70 mm. Gas plasma is generated by applying high frequency waves of 13,56 MHz, 1500W, to the first ring antenna 63, and high frequency waves of 13,56 MHz, 1000W, to the second ring antenna 64, and the oxide film is etched by applying bias of 800 kHz, 1200W to the process platform 5. Under the above condition, the electronic temperature around the first ring antenna 63 is approximately 10 eV, and the electronic temperature around the wafer is approximately 4 eV. The etching velocity of the oxide film is approximately 700 nm/min, and the selection ratio to the resist becomes approximately 25. However, the etching termination can be observed at the middle of the contact holes.

Then, the high frequency power applied to the second ring antenna 64 is altered to 500 w, and the frequency is changed to 100 MHz. The electronic temperature around the wafer is decreased to approximately 2 eV. Because the plasma density is mainly determined by the first ring antenna 63, wherein the high power is introduced, the ion current density is not changed, and the etching velocity of the oxide film is approximately 700 nm/min, but the selection ratio to the resist is decreased to approximately 10 by lowering the electronic temperature. However, under this condition, the etching termination is not generated.

If the high frequency power to be applied to the second ring antenna 64 is changed from 1000 W to 500 W in accordance with elapsing the etching time at a constant frequency of 100 MHz, the etching process is not terminated, the contact holes are formed, and average selection ratio to the resist during the etching process becomes approximately 20.

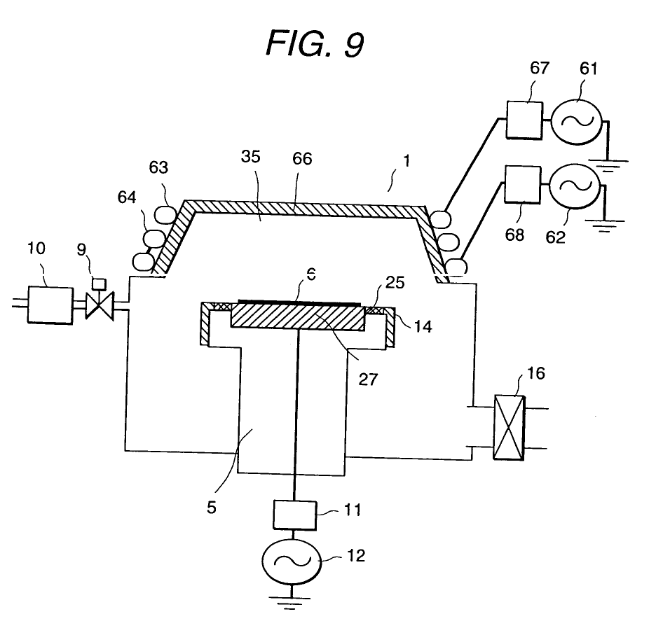

The pressure of the gas introduced in the plasma treating chamber 35 is as same as the previous embodiment, such as the range from 0.1 Pa to 4 Pa is adoptable. As explained above, even in accordance with the induction coil type plasma, not the ECR type, the electronic temperature in the plasma treating chamber can be controlled by providing plural induction coils and controlling the frequency and the power of the high frequency waves applied to each of the induction coils. By performing the dissociation control of CF group gas with the method explained above, the etching process satisfying the etching depth and the selection ratio becomes available. Substantially, the present method is also based on the same principle as the ECR method, and the operations such as adjustment of the gap and the like are similar. If the wafer facing plane is composed of a dielectric material reactive with the etching gas (single crystal Si, quartz, alumina, and the like), a reaction is generated at its surface, and control of etching species becomes possible as stated previously. Because the present apparatus is induction combination type, electrical conductive materials (Si or SiC doped with Aluminum, P, B, and soon) can be used for composing the wafer facing plane. The apparatus structure indicated in FIG. 9 is substantially similar with the apparatus indicated in FIG. 10 the apparatus indicated in FIG. 9 comprises somewhat slanted side wall, different from the apparatus indicated in FIG. 10 wherein two sets of antennas are provided on the wafer facing planes, and two sets of antennas 63, 64 are provided on the side wall. The present apparatus differs from the apparatus in FIG. 10 only in the location of the antennas, and operation and advantages of the present invention are similar. The same advantages can be obtained, even if the etching chamber is made cylindrical shape as indicated in FIG. 10, and the antennas are provided on the side wall portion. In accordance with the apparatus indicated in FIG. 9, the components designated by the same numerical marks as FIG. 1 and FIG. 10 have the same functions (the exhaust system is omitted), and explanation in details is omitted.

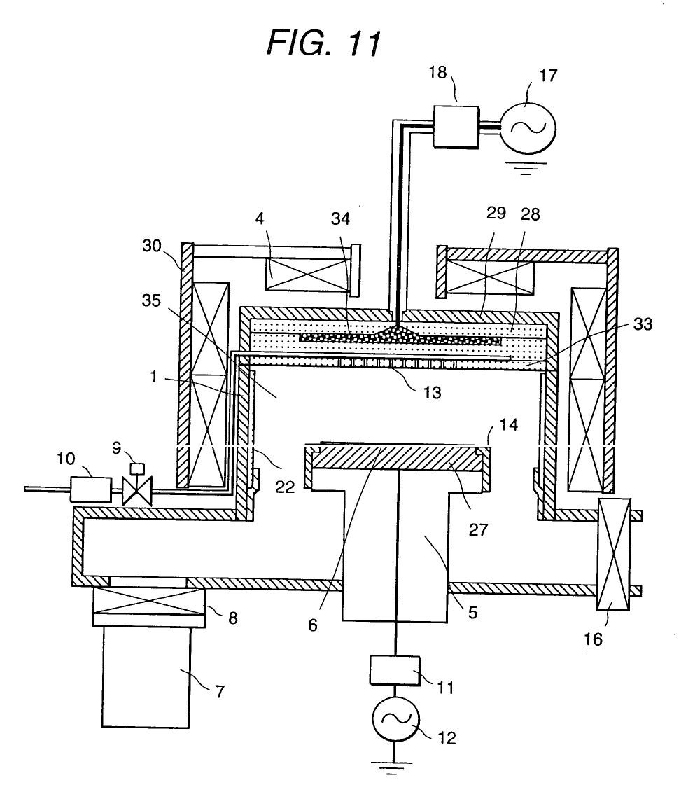

Another embodiment using the apparatus indicated in FIG. 11 is explained, hereinafter.

In accordance with the present apparatus, plasma treating chamber 35, atmospheric antenna 34, antenna dielectric 28, quartz 33, dielectric having a gas inlet 13, and process platform are provided in the etching treatment chamber 1. An etching gas is introduced into the plasma treating chamber 35 via the gas inlet of the dielectric 13, and gas plasma is generated by introducing the electromagnetic waves of 300 MHz to 600 MHz generated by the high frequency power source 17 into the plasma treating chamber 35 via the matching box 18 and the atmospheric antenna 34. In order to make the electromagnetic waves be propagated effectively to the plasma treating chamber 35, the outer diameter of the antenna 34, and size and material of the antenna dielectric 28 are determined so as to make the electromagnetic waves cause a resonance with a desired mode (here, TMO1) between the atmospheric antenna 34 and the antenna earth 29. The electromagnetic waves cause a resonance between the antenna 34 and the antenna earth 29, and are propagated to the plasma treating chamber 35 via the quartz plate 33 through the peripheral portion of the antenna dielectric 28. In order to discharge effectively, three solenoid coils 4 for generating magnetic field contained in a coil case 30, respectively, are arranged at peripheral portion of the etching treatment chamber, and a coil current is set in order to form a magnetic field between 0 to 320 Gauss at approximately above the process platform 5. Then, high density plasma having an electronic density of at least 10¹¹ electrons/cm³ is generated using electron-cyclotron resonance. The process platform 5 is provided in the plasma treating chamber 35. A member to be treated 6 is placed on the process platform 5, and etched with the gas plasma. The etching gas is introduced into the etching treatment chamber 1 through the gas flow controller 10 and the valve 9, and exhausted outside the etching treatment chamber 1 by the exhaust pump 7. The pressure in the plasma treating chamber 35 is controlled to be a designated value by a conductance valve 8 provided on the top of the exhaust pump 7. The process platform 5, whereon the wafer is placed, is provided with the high frequency power source 12 and the matching box 11, which can supply high frequency bias from 400 kHz to 13.56 MHz. An inner cylinder made of quartz 22 is arranged at the side wall portion of the plasma treating chamber 35, and an earth 2 is provided concurrently for supporting the inner cylinder 22.

As the member to be treated, eight inches silicone wafer having the structure indicated in FIG. 12 formed on its surface is transferred from an adjacent transfer chamber (not shown in the figure) via the gate valve 16. The left figure in FIG. 12 indicates across section 121 before etching. On the silicone wafer 129, the gate oxide film 128 of 4 nm thick is formed, whereon p-type polycrystalline Si film 126 of 100 nm thick and n-type polycrystalline Si film 127 of 100 nm thick are formed in a mixed manner, and further WN film 125 of 10 nm thick and W film 124 of 100 nm thick are formed thereon. On the W film, an oxide film 123 of 100 nm thick, which has been manufactured for patterning with width of 140 nm as an etching mask, is formed.

A mixed gas consisting of CF₄ gas 45 ml/min, HBr gas 15 ml/min, O₂ gas 25 ml/min, and N₂ gas 8 ml/min is introduced into the plasma treating chamber 35 through the gas inlet formed on the dielectric 13, and pressure of the gas is maintained at 0.5 Pa. Gas plasma is generated by applying electromagnetic waves of 450 MHz, 600 W, and the W film and the WN film are etched by applying bias of 400 kHz, 60W to the process platform 5. The distance (gap) from the wafer 6 placed on the process platform 5 to the dielectric 13, which corresponds to the wafer facing plane, is set as 70 mm. The coil current is adjusted to make the magnetic field intensity 160 Gauss at a position far from the wafer 6 by 60 mm on the wafer, and to make the magnetic field gradient 15 gauss/cm at the same positions (ECR height). The magnetic field intensity of 160 gauss is a magnetic field intensity to satisfy the ECR condition, and a ration of magnetic field gradient/magnetic field intensity is 0.09 Gauss/cm. Under the above condition, the thickness of the ECR region corresponding to the high electronic temperature region is approximately 15 mm, and the electronic temperature is approximately 8 eV. The electronic temperature in the region other than the ECR region, which corresponds to the low electronic temperature region, is approximately 2 eV.

After etching the W film and the WN film, Cl₂ gas ml/min, HBr gas 80 ml/min, O₂ gas 4 ml/min are introduced into the plasma treating chamber 35, and plasma is generated by applying the electromagnetic waves of 450 MHz, to the atmospheric antenna 34 by 500 W. The ion current density injected into the wafer 6 is approximately 1.5 mA/cm². The power of the high frequency bias applied to the wafer 6 is set at 40 W to perform etching of the p-type and n-type polycrystalline Si. When the etching is proceeded to the gate oxide film 128, the flow of the Cl gas is stopped, the introducing flow of HBr gas is changed to 70 ml/min, the introducing flow of O₂ gas is changed to 6 ml/min, and the gas pressure is changed to 0.4 Pa.

Because the dissociation of Cl₂ requires an energy of approximately 2.5 eV, the dissociation of Cl₂ is not proceeded in the low electronic temperature region, and the injection amount of Cl radicals are decreased. Therefore, side etching at the side plane of the n-type polycrystalline Si is suppressed significantly, and the n-type polycrystalline Si can be manufactured perpendicularly approximately as same as the p-type polycrystalline Si (the right FIG. 122 in FIG. 12 indicates the shape after etching). The etching in a depth direction is proceeded by dissociation-adsorption of Cl₂ and ion injection. Therefore, even if the number of the Cl radicals are decreased, the etching velocity is not changed as approximately 200 nm/min.

Under the condition that the magnetic field gradient is 0.5 Gauss (the ratio of magnetic field gradient/magnetic field intensity becomes 0.003 Gauss/cm), the high electronic temperature region is extended, and the dissociation of Cl₂ is enhanced. Accordingly, the injection amount of Cl radicals to side plane of the groove is increased, and side etching is readily generated on the n-type polycrystalline Si. If the flow of O₂ gas is increased to 8 ml/min in order to decrease the side etching, a strong protective film is formed on the side plane of the p-type polycrystalline Si, fattening of the shape (tapered shape) is generated, and obtaining the same perpendicular shape as the n-type polycrystalline Si becomes difficult.

Even if the gas pressure is increased from 0.4 Pa to 0.8 Pa, the perpendicular shape can be obtained. However, it the gas pressure is increased equal to or higher than 1.2 Pa, the fattening is generated in manufactured shape in the isolated pattern. If the gas pressure is decreased to 0.15 Pa, almost similar shape as the etched shape at 0.4 Pa can be obtained. However, if the gas pressure is decreased further lower than 0.1 Pa, the electronic temperature in the low electronic temperature region is elevated, and dissociation of Cl₂ is enhanced. Therefore, decreasing the difference in manufactured shapes of the p-type and the n-type becomes difficult.

After etching the polycrystalline Si, the gas pressure is increased to 0.8 Pa, in order to prevent generation of etching residue, and the polycrystalline Si is treated with HBr gas 90 ml/min, and O₂ gas 7 ml/min for 15 seconds.

As explained above, even in the manufacturing the gate electrode, side etching can be suppressed by controlling the two electronic temperature regions, and almost similar manufactured shapes can be obtained with both p-type and n-type polycrystalline Si.

Even in the case of manufacturing metallic circuit including Cl₂ gas and BCl₃ gas, the amount of Cl radicals is decreased and perpendicularly manufacturing becomes easy by similarly broadening the low electronic temperature region.

In the case of etching an effective insulating film with N₂ gas and H₂ gas, the etching can be proceeded so as to flatten the bottom plane of the holes or grooves by controlling the two electronic temperature regions so as to make the electronic temperature on the wafer low, because dissociation of reaction products are suppressed and unnecessary accumulation can be avoided. The same result can be obtained with NH₃ gas.

Next, another embodiment using the apparatus indicated in FIG. 1 is explained.

Eight inches silicone wafer is transferred into the apparatus as the member to be treated. On the silicone wafer, a gate electrode is formed, whereon a silicone nitride film is formed, whereon an oxide film of 0.7 μm thick is formed, and a resist mask reprinted with a mask pattern is formed thereon. Holes having 250 nm in diameter are formed on the resist mask. Practically, the structure is similar with the cross sectional shape 88 before etching in FIG. 8, and the distance from the upper portion of the oxide film to closest silicone nitride film is approximately 0.4 μm.

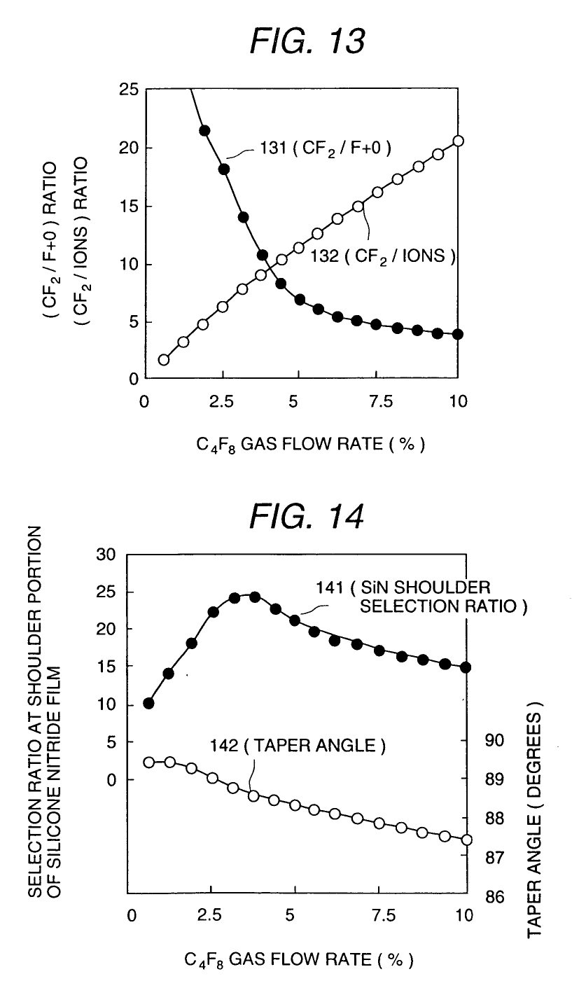

A mixed gas consisting of Ar 400 ml/min, C₄F₈, and O₂ is introduced into the plasma treating chamber 35 of the apparatus through the gas inlet 24, and the gas pressure is maintained at 2 Pa. Gas plasma is generated with high frequency waves of 450 MHz, 1.3 kW, and etching the oxide film is performed by applying the high frequency bias of 400 kHz, 1000W, to the process platform 5. To the antenna 23, the bias of 400 W is applied from another high frequency power source 20 of 85 kHz. The process platform 5 is set at a position separated from the antenna 23 by 80 mm. The coil current is adjusted to make the magnetic field intensity 160 Gauss at a position far from the wafer 6 by 50 mm on the central portion of the wafer, to make the magnetic field gradient 15 gauss/cm at the same positions, and to make the magnetic field intensity 160 Gauss at a position above the peripheral portion of the wafer by 60 mm. Under the above condition, the thickness of the ECR region corresponding to the high electronic temperature region 101 is approximately 35 mm, and the electronic temperature is approximately 8 eV. The electronic temperature in the region other than the ECR region corresponding to the low electronic temperature region 102 is approximately 2 eV. The ion current density is approximately 5 mA/cm². Under the above condition, the etching treatment is performed using C₄F₈ gas flow in the range from 4 ml/min to 40 ml/min. The flow rate of O₂ was adjusted so that the O₂/C₄F₈ ratio becomes 0.5. The etching velocity of the oxide film is increased with increasing the flow rate of C₄F₈ gas. The injection ratio of CF₂/(F+O) and the injection ratio of CF₂/ions onto the wafer depend on the C₄F₈ gas flow rate as indicated by the curve 131 and 132 in FIG. 13, respectively. Here, because O radical etches the silicone nitride film, injection of O is taken into consideration. It is revealed that if the C₄F₈ gas flow rate is small, the silicone nitride film is not protected by CF₂, and if the C₄F₈ gas flow rate is increased, the silicone nitride film is etched by F and O. The dependency of selection ratio of shoulder portion of the silicone nitride film on the C₄F₈ gas flow rate is indicated by the curve 141 in FIG. 14.

The selection ratio of shoulder portion of the silicone nitride film is decreased by ion spattering at low C₄F₈ gas flow rate, and by etching with F and Oat high C₄F₈ gas flow rate. Under the above condition, the optimum high C₄F₈ gas flow rate is in the range approximately from 2% to 5%. Under the same condition, if kind of the gas is changed to C₆F₈, the C₆F₈ gas flow rate in the range from 1% to 3% becomes optimum. In FIG. 14, the curve 141 corresponds to the injection ratio of CF₂/(F+O), and the curve 142 corresponds to the injection ratio of CF₂/ions. As indicated by the curve 142, the perpendicularity (taper angle) of the manufactured shape is determined by the injection ratio of CF₂/ions, and the manufactured shape becomes desirable perpendicular shape at low C₄F₈ gas flow rate.

In accordance with the present invention, the generation ratio of CF₂/F can be set or controlled arbitrarily using CF group treating gas. Therefore, oxide film etching, which does not depend significantly on gas pressure and gas flow rate, having a high selection ratio to resist and nitride film becomes possible. By utilizing the present invention, contact holes having a high aspect ratio, and an oxide film having a high selection ratio to resist and silicone nitride film can be manufactured. Because the above etching can be performed under a low gas pressure condition in the range from 1 Pa to 4 Pa, a perpendicularly manufactured shape can be obtained with contact holes having a high aspect ratio.

What is claimed is:

1. A dry etching method comprising the steps of:
generating electromagnetic waves and magnetic field in an etching treatment chamber under vacuum,
generating plasma by electron-cyclotron resonance, and
etching the member to be treated such as wafer (hereinafter, called “wafer”), wherein
a distance between an antenna, which is arranged in said etching treatment chamber and injects the electromagnetic waves, and said wafer is set at a value in the range from 30 mm to 100 mm,
the frequency of said electromagnetic waves is set at a value in the range from 300 MHz to 600 MHz,
a magnetic field gradient is set,
two kinds of electronic temperature regions are generated between said antenna and the wafer, and
an etching treatment is performed in a condition, that a gas pressure in said etching treatment chamber is in the range from 0.1 Pa to 4 Pa.

2. A dry etching method as claimed in claim 1, further comprises the steps of:
introducing a gas consisting of at least carbon and fluorine into said etching treatment chamber,
generating F (fluorine radicals) and ions corresponding to CF₂ in said plasma, each amount of which is independent each other, and
performing said etching treatment.

3. A dry etching method as claimed in claim 2, further comprises the steps of:
introducing a gas consisting of at least carbon and fluorine into said etching treatment chamber,
determining power of a high frequency power source for generating said high electromagnetic waves, and
performing said etching treatment.

4. A dry etching method as claimed in claim 1, further comprises the steps of:
generating electromagnetic waves and magnetic field in said etching treatment chamber,
generating plasma by electron-cyclotron resonance (ECR), and
performing said etching treatment.

5. A dry etching method as claimed in claim 1, further comprises the steps of:
introducing a gas consisting of at least carbon and fluorine into said etching treatment chamber,
generating electromagnetic waves and magnetic field in said etching treatment chamber,
generating plasma by electron-cyclotron resonance (ECR),
determining position of ECR,
generating F (fluorine radicals) and ions corresponding to CF₂ in said plasma, each amount of said F and said ions is independent each other, and
performing said etching treatment.

6. A dry etching method as claimed in claim 1, further comprises the steps of:
introducing a gas consisting of at least carbon and fluorine into said etching treatment chamber with a pre-determined flow rate, and
performing said etching treatment.

7. A dry etching method as claimed in claim 1, further comprises the steps of:
generating F (fluorine radicals) and ions corresponding to CF₂ in said plasma, each amount of said F and said ions is independent each other, in correspondence to an etching process of insulating film, and
performing said etching treatment.

8. A dry etching method comprising the steps of:
introducing a gas consisting of at least carbon and fluorine into an etching treatment chamber under vacuum,
generating electromagnetic waves and magnetic field in said etching treatment chamber,
generating plasma by electron-cyclotron resonance, and
performing an etching treatment with a wafer, wherein
a distance between an antenna, which is arranged in said etching treatment chamber and injects the electromagnetic waves, and said wafer is set at a value in the range from 30 mm to 100 mm,
a magnetic field gradient is controlled by setting the frequency of said electromagnetic waves at a value in the range from 300 MHz to 600 MHz,
a generation ratio of CF₂/F is controlled by varying two kinds of electronic temperature regions between said antenna and the wafer, and
an etching treatment is performed.

9. A dry etching method as claimed in claim 8, wherein
said etching treatment is performed in a manner that an electronic temperature around the wafer is decreased in accordance with elapsing the etching time corresponding to the etching treatment for contact holes of said wafer.

10. A dry etching method comprising the steps of:
generating electromagnetic waves and magnetic field in an etching treatment chamber under vacuum,
generating plasma by electron-cyclotron resonance, and
performing an etching treatment with a wafer, wherein
a distance between a wafer facing plane, which is arranged in said etching treatment chamber, and said wafer is set at a value in the range from 30 mm to 100 mm,
a magnetic field gradient is determined by setting the frequency of said electromagnetic waves at a value in the range from 300 MHz to 600 MHz,
two kinds of electronic temperature regions are generated between said wafer facing plane and said wafer, and
an etching treatment is performed in a condition, that a gas pressure in said etching treatment chamber is in the range from 0.1 Pa to 4 Pa.

11. A dry etching method as claimed in claim 10, wherein
said etching treatment is performed by determining power of the high frequency power source for generating said electromagnetic waves.

12. A dry etching method as claimed in claim 11, wherein
two kinds of electronic temperature regions are generated between said wafer facing plane and said wafer,
radicals and ions contributing to said etching treatment in plasma are generated, each amount of said radicals and said ions is independent each other, and
performing said etching treatment.

13. A dry etching method as claimed in claim 10, wherein
electromagnetic waves and magnetic field are generated in said etching treatment chamber,
plasma is generated by electron-cyclotron resonance (ECR),
determining position of ECR, and
performing said etching treatment.

14. A dry etching method as claimed in claim 13, wherein
a gas consisting of at least carbon and fluorine is introduced into said etching treatment chamber,
two kinds of electronic temperature regions are generated between said wafer facing plane and said wafer,
F (radicals) and ions corresponding to CF₂ in plasma are generated, each amount of said radicals and said ions is independent each other, and
said etching treatment is performed.

15. A dry etching method as claimed in claim 14, wherein
said etching treatment is performed by determining said magnetic field gradient and the flow rate of said gas consisting of at least carbon and fluorine.

16. A dry etching method as claimed in claim 14, wherein
F (fluorine radicals) and ions corresponding to CF₂ in said plasma are generated, each amount of said F and said ions is independent each other, in correspondence to an etching process of the oxide film, and
said etching treatment is performed.

17. A dry etching method comprising the steps of:
generating electromagnetic waves and magnetic field in an etching treatment chamber,
generating plasma by electron-cyclotron resonance, and
performing an etching treatment with a wafer, wherein
a distance between a wafer facing plane, which is arranged in said etching treatment chamber, and said wafer is set at a value in the range from 30 mm to 100 mm,
a magnetic field gradient is determined by setting the frequency of said electromagnetic waves at a value in the range from 300 MHz to 600 MHz,
the generation ratio of CF₂/F is controlled by making two kinds of electronic temperature regions, which are generated between said wafer facing plane and said wafer, variable by controlling the magnetic field gradient, and
the etching treatment is performed.

18. A dry etching method comprising the steps of:
introducing a gas consisting of at least carbon and fluorine into an etching treatment chamber under vacuum,
generating plasma by electron-cyclotron resonance, and
performing an etching treatment with a wafer, wherein
a distance between a wafer facing plane, which is arranged in said etching treatment chamber, and said wafer is set at a value in the range from 30 mm to 100 mm,
each of frequencies of a high frequency power source for generating first electromagnetic waves and a high frequency power source for generating second electromagnetic waves is set at a value in the range from 300 MHz to 600 MHz, respectively,
high frequency bias having a lower frequency either of the first electromagnetic waves and the second electromagnetic waves is applied to a process platform, the wafer is treated thereon,
two kinds of electronic temperature regions are generated between said wafer facing plane and said wafer,
F (fluorine radicals) and ions corresponding to CF₂ are generated, each amount of said F and said ions is independent each other, and
an etching treatment is performed in a condition, that a gas pressure in said etching treatment chamber is in the range from 0.1 Pa to 4 Pa.

19. A dry etching method comprising the steps of:
introducing a gas including at least Cl or Br into an etching treatment chamber under vacuum,
generating electromagnetic waves and a magnetic field,
generating plasma by electron-cyclotron resonance, and
performing an etching treatment with a wafer, wherein
a distance between a wafer facing plane, which is arranged in said etching treatment chamber, and said wafer is set at a value in the range from 30 mm to 100 mm,
a magnetic field gradient is determined by setting frequency of the electromagnetic waves at a value in the range from 300 MHz to 600 MHz, respectively,
two kinds of electronic temperature regions are generated between said wafer facing plane and said wafer,
Cl radicals or Br radicals, and ions are generated, wherein a generation amount of said Cl radicals or Br radicals, and a generation amount of said ions are independent each other, in correspondence to an etching process of gate electrodes including polycrystalline Si or metallic circuit including Al, and an etching treatment is performed.

20. A dry etching method comprising the steps of:
generating plasma in an etching treatment chamber by high frequency waves, and
performing an etching treatment with a wafer, wherein
a distance between a wafer facing plane, which is arranged in said etching treatment chamber, and said wafer is set at a value in the range from 30 mm to 100 mm,
frequency of said high frequency waves is set at a value in the range from 10 MHz to 100 MHz,
an electronic temperature region depending on said high frequency is generated, and
a SAC manufacturing is performed selectively on an oxide in comparison with silicone nitride film in a condition, that a gas pressure in said etching treatment chamber is in the range from 0.1 Pa to 4 Pa.

21. A dry etching method as claimed in any one of claims 1 to 15, 17, and 19, wherein
said magnetic field gradient in said electron-cyclotron resonance (ECR) region is set so that a ratio of magnetic field gradient/magnetic field intensity is in the range from 0.15/cm to 0.01/cm.

22. A dry etching method as claimed in any one of claims 1 to 21, wherein
high frequency bias of 400 kHz to 13.56 MHz is applied to said process platform for wafer.
